(19) United States
(12) Patent Application Publication
(10) Pub. No.: US 2009/0302228 A1
(43) Pub. Date: Dec. 10, 2009

(54) DEVICE FOR QUANTIFICATION OF RADIOISOTOPE CONCENTRATIONS IN A MICRO-FLUIDIC PLATFORM

(75) Inventors: Arion-Xenofon F. Hadjioannou, Los Angeles, CA (US); Vu Nam, Torrance, CA (US); Tak For Yu, Los Angeles, CA (US); Hsian-Rong Tseng, Los Angeles, CA (US)

Correspondence Address: VENABLE LLP, P.O. BOX 34385, WASHINGTON, DC, 20043-9998, US

(73) Assignee: THE REGENTS OF THE UNIVERSITY OF CALIFORNIA, Oakland, CA (US)

(21) Appl. No.: 12/296,825

(22) PCT Filed: Apr. 20, 2007
(86) PCT No.: PCT/US2007/009705

§ 371 Date: Oct. 10, 2008

Related U.S. Application Data
(60) Provisional application No. 60/793,241, filed on Apr. 20, 2006.
(60) Provisional application No. 60/832,615, filed on Jul. 24, 2006.

(51) Int. Cl. G01T 1/26; H01L 31/02

(52) U.S. Cl. 250/370.08; 250/371

(57) ABSTRACT

A micro-fluidic device has a micro-fluidic circuit layer and a charged-particle detection layer disposed proximate the micro-fluidic circuit layer. The micro-fluidic device is constructed to provide a two-dimensional image of charged-particle emissions from a sample within the micro-fluidic circuit layer while in operation. A method of quantification of radioactivity in a biological sample includes directing a fluid containing the biological material into a microfluidic device, detecting charged particles emitted from the biological material with a two-dimensional imaging sensor, and forming a two-dimensional image over time corresponding to radioactivity of the biological sample.

### CROSS-REFERENCE OF RELATED APPLICATION

This application claims priority to U.S. Provisional Application No. 60/793,241, filed Apr. 20, 2006 and U.S. Provisional Application No. 60/832,615, filed Jul. 24, 2006, the entire contents of which are hereby incorporated by reference.

### FIELD OF INVENTION

The present invention relates to micro-fluidic devices and more particularly micro-fluidic devices that have a charged-particle detector and/or an optical detection structure.

### BACKGROUND

Imaging probes dedicated to the detection of positrons and other charged particles have been developed for intra-operative operation. (See Hoffman, E. J., Tornai, M. P., Levin, C. S., MacDonald, L. R. & Siegel, S. Design and performance of gamma and beta intra-operative imaging probes, Physica Medica 13, 243-246 (1997); Macdonald, L. R. et al. Investigation of the Physical Aspects of Beta-imaging Probes Using Scintillating Fibers and Visible-Light Photon Counters. IEEE Transactions on Nuclear Science 42, 1351-1357 (1995); Tornai, M. P., MacDonald, L. R., Levin, C. S., Siegel, S. & Hoffman, E. J. Design considerations and initial performance of a 1.2 cm(2) beta imaging intra-operative probe, IEEE Transactions on Nuclear Science 43, 2326-2335 (1996); and Barthe, N., Chatti, K., Coulon, P., Maitrejean, S. & Basse-Cathalinat, B. Recent technologic developments on high-resolution beta imaging systems for quantitative autoradiography and double labeling applications. Nuclear Instruments & Methods in Physics Research Section A: Accelerators Spectrometers Detectors and Associated Equipment 527, 41-45 (2004).) The most common intra-operative charged particle detection probes that have enjoyed commercial success are non-imaging types (http://www.intra-medical.com/beta.html). There have been other devices developed for autoradiography imaging and quantification of beta particles, based on various technologies. These are optimized for imaging excised tissue sections (http://www.biomolex.com/, http://www.biospace.fr/en/mi.php). However, microfluidic chips are not currently available that have such charged particle detectors for the detection of and imaging of live cells incubated at 37° C., for example. Conventional devices do not have close integration of charged particle detectors with a microfluidic chip, and in particular do not also provide high sensitivity, versatility and low cost. There is thus a need for improved micro-fluidic devices.

All references cited anywhere in this specification are incorporated herein by reference.

### SUMMARY

A micro-fluidic device according to an embodiment of the current invention has a micro-fluidic circuit layer and a charged-particle detection layer disposed proximate the micro-fluidic circuit layer. The micro-fluidic device is constructed to provide a two-dimensional image of charged-particle emissions from a sample within the microfluidic circuit layer while in operation.

A method of quantification of radioactivity in a biological sample according to an embodiment of the current invention includes directing a fluid containing the biological material into a microfluidic device, detecting charged particles emitted from the biological material with a two-dimensional imaging sensor, and forming a two-dimensional image corresponding to radioactivity of the biological sample.

### BRIEF DESCRIPTION OF THE DRAWINGS

FIG. 1 is a schematic illustration of a microchip-based protein array that can be utilized for quantification of the dynamic interactions between surface-immobilized protein and charged particle-emitting probes according to an embodiment of the current invention. When surface-immobilized proteins are replaced by cells, this device can be utilized as a microchip-based cellular array for quantification of the dynamic interactions between surface-immobilized cells and imaging probes.

FIG. 2(a) is a schematic illustration, in cross section, of a microfluidic device having a scintillation radiation detector according to an embodiment of the current invention. The current example has a 10 micron end layer between the fluidic channels and the scintillator. The scintillator in this example is coupled through a lens to a Charge Coupled Device (CCD) imaging sensor.

FIG. 2(b) is a schematic illustration of a microfluidic device according to another embodiment of the current invention. For improved light collection, the CCD can be coupled to the imaging sensor through a fiber-optic plate.

FIG. 3(a) shows scintillation light detected from ¹⁸F overlaid with a photographic image of the scintillator.

FIG. 3(b) shows scintillation light detected in regions of interest as a function of ¹⁸F source activity.

FIG. 4 shows multiple wells of 1 mm diameter filled with FDG and separated by x=1 mm, y=1.5 mm and z=3 mm.

FIG. 5 shows a miniaturized cell incubation chamber where about 500 NIH3T3 cells are maintained for 7 days.

FIG. 6 is a schematic illustration of a microfluidic circuit for production of FLT and FDDNP. An additional column module is incorporated for on-chip purification of FLT and FDDNP produced by the round-shaped reaction chamber.

FIG. 7 is a schematic illustration of portions of a microfluidic device according to an embodiment of the current invention for (a) a UV-Vis microcell and (b) a fluorescent microcell integrated with a chemical reaction circuit and a radio-detector.

FIG. 8 shows a microcolumnar structure of a CsI scintillator crystal.

FIG. 9 is a schematic illustration of an embodiment of a microfluidic device, in cross section, according to an embodiment of the current invention. This embodiment includes a solid state detector instead of a scintillator and optical imaging sensor.

FIG. 10(A) shows a microfluidic line pair chip filled with FDG in which line pairs have a variable center to center separation of 0.5 mm. In this embodiment, the 0.5 mm line pairs are resolved.

FIG. 10(B) is a photograph of microfluidic chip with a small rectangular microwell measuring 0.25 mm on its side according to an example of the current invention.

FIG. 10(C) shows a positron image acquired from a microwell chip filled with 4.33 nCi of FDG according to an example of the current invention.

FIG. 11 shows measured net counts per minute after background subtraction plotted with the theoretical ¹⁸F decay curve shown as a dashed line.

FIG. 12 is a schematic illustration of a microfluidic device, in cross section, according to an embodiment of the current invention. In the center of the chip is a microfluidic channel where radioactive cells and solutions can be loaded. Beneath the channel are a series of substrate layers that can be used to control the flow of solutions. The PSAPD is sealed from visible light with an aluminized Mylar film and protected by a sacrificial Mylar film.

FIG. 13 is a photograph of a PSAPD detector top surface with readout electronics hidden underneath and inside a protective metal enclosure.

FIG. 14(a) is a photograph of a microfluidic chip with tubing for pneumatic control of valves on top of a PSAPD detector according to an embodiment of the current invention.

FIG. 14(b) shows an image of FDG uptake in 3T3 mouse fibroblast cells using a PSAPD sensor according to an embodiment of the current invention.

FIG. 14(c) is a photograph of live cells taken with a microscope corresponding to FIG. 14(b).

### DETAILED DESCRIPTION

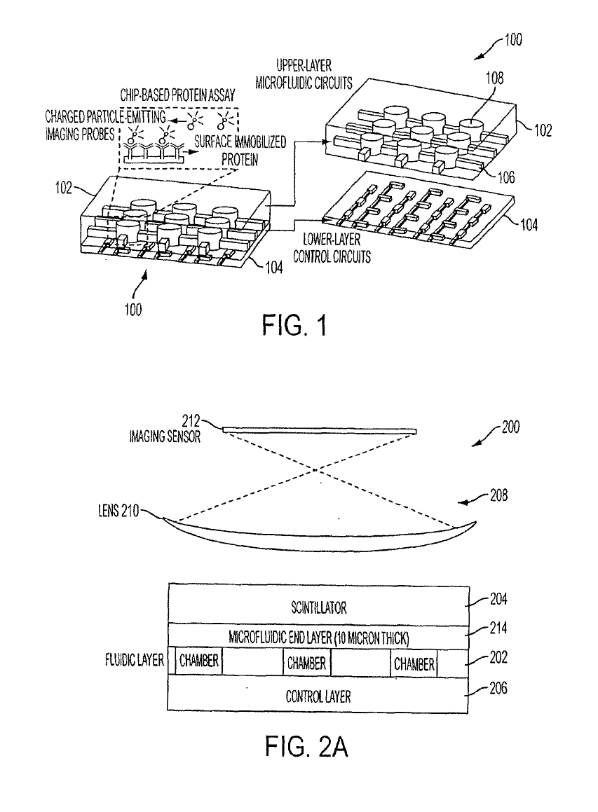

FIG. 1 is a schematic illustration of some structural components of a microfluidic device 100 according to an embodiment of the current invention. The microfluidic device 100 has a microfluidic circuit layer 102 and a control circuit layer 104. The microfluidic circuit layer 102 may be constructed from organic and/or inorganic materials, for example, but not limited to, PDMS formed using a template. The template may be constructed using photolithographic techniques. For example, one may deposit a photoresist on a substrate, such as a silicon substrate, expose the photoresist in a desired pattern through a photomask and then etch the exposed substrate. This process can be repeated to form more complex patterns, if desired. The microfluidic circuit layer 102 can be constructed to define a plurality of microchannels, such as microchannel 106 providing one possible example. In addition, the microfluidic circuit layer 102 can be constructed to define a plurality of chambers such as chamber 108. The microfluidic channels and chambers can be constructed to direct a flow of and/or contain a biologic material, for example, a biologic material that has charged particle emitters attached to and/or incorporated into its composition.

The control circuit layer 104 operates to open and close valves to control the flow and/or isolation of a fluid or a plurality of fluids that can be introduced into channels and/or chambers of the microfluidic circuit 102. In an embodiment of the current invention, the control circuit 104 is also a microfluidic circuit having a plurality of valve actuators that can be operated by a fluid to stop or permit fluid flow past a proximate region of the microfluidic circuit 102. The general concepts of this invention are not limited to only control circuits that operate using an applied fluid. For example, the control circuit 104 could be a mechanically and/or electro-mechanically operable control circuit without departing from the broad concepts of the current invention.

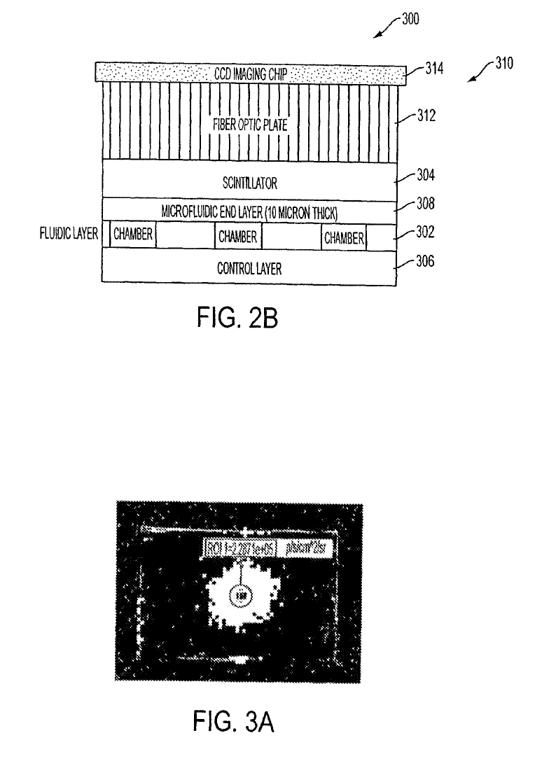

FIG. 2(a) is a schematic illustration of a microfluidic device 200 according to an embodiment of the current invention. The microfluidic device 200 has a microfluidic circuit layer 202 and a charged particle detection layer 204. The microfluidic circuit layer may be similar to or substantially the same as microfluidic circuit layer 102. In addition, the microfluidic device 200 may also include a control circuit layer 206. The control circuit layer 206 may be similar to or substantially the same as control circuit layer 104. In this example, the charged particle detection layer 204 is on an opposing side of the microfluidic circuit layer 202 relative to the control circuit layer 206. The invention is not limited to only such an arrangement. For example, the control circuit 206 could be arranged between the microfluidic circuit layer 202 and the charged particle detection layer 204 according to other embodiments of the current invention. Charged particles generally interact strongly with matter and thus have a relatively short mean free path through dense materials such as liquids and solids, for example as compared to the 511 keV gamma rays that are produced by the annihilation of an electron-positron pair. Therefore, some embodiments of the current invention will seek to arrange the charged particle detection layer 204 close to the microfluidic circuit layer 202 with only thin layers of dense material therebetween. This can help to improve the detection efficiency and imaging resolution. In cases where it is desirable to keep the charged particle detection layer 204 isolated from fluid within the microfluidic circuit layer, a thin microfluidic end layer 214 may be included. The microfluidic end layer 214 can be a 10 micrometer thick layer of PDMS, for example. However, the broad aspects of the invention are not limited to these specific design features. The microfluidic end layer 214 can facilitate the separation of the charged particle detection layer 204 from the microfluidic circuit 202, for example, in cases in which the microfluidic circuit 202 is disposable but it is desirable to reuse the charged particle detection layer 204. The charged particle detection layer 204 layer is a scintillator material layer in the example illustrated in FIG. 2(a).

The microfluidic device 200 also has a detection system 208 that detects photons produced by the charged particles that travel into the charged particle detection layer 204. The detection system 208 may include a lens system 210 and an imaging sensor 212. The lens system 210 can be a single lens or a plurality of lenses as desired to form an image of light collected from the charged particle detection layer 204 onto the imaging sensor 212 of the desired image quality. The imaging sensor can be, but is not limited to, a CCD imaging chip.

FIG. 2(b) is a schematic illustration of a microfluidic device 300 according to another embodiment of the current invention. The microfluidic device 300 has a microfluidic circuit layer 302 and a charged particle detection layer 304. In addition, the microfluidic device 300 may also include a control circuit layer 306. The microfluidic circuit layer 302, charged particle detection layer 304, and control circuit layer 306 can be similar to or substantially the same as microfluidic circuit layer 202, charged particle detection layer 204, and control circuit layer 206, respectively. The microfluidic device 300 can also include a microfluidic end layer 308, similar to microfluidic end layer 214. In this embodiment, the microfluidic device 300 has a detection system 310 that comprises a fiber-optic plate 312 disposed on the charged particle detection layer 304 and an imaging sensor 314 disposed on the fiber-optic plate 312. The imaging sensor 314 can be, but is not limited to, a CCD imaging chip. The fiber-optic plate 312 in this embodiment acts to channel photons from the surface of the charged particle detection layer 304 to the imaging sensor 314 while substantially maintaining a relative spatial position compared to neighboring photons to thereby preserve a high degree of resolution of a two-dimensional image.

### EXAMPLE 1

A collaboration between the Hadjioannou's and Tseng's research groups in the Department of Molecular and Medical Pharmacology and the Crump Institute for Molecular Imaging at UCLA has led to the development of a new technology by integrating microfluidic circuits with a charged particle (e.g., electron, positron and alpha particle) position sensitive radiation detector. This invention can handle very small amounts of radio-labeled probe molecules and quantify these probe molecules with a two-dimensional (2-D) resolution as a function of time in the integrated device. When compared with existing technologies (e.g., PET or SPECT tomographic systems) this invention can provide significantly (log orders) improved sensitivity −100 pCi and spatial resolution ˜0.01 mm², as well as dramatically reduced cost. This can be utilized to quantify multiple aspects of microchip-based chemical and biological operations. Examples include:

(i) A microchip-based protein array (FIG. 1) that can be used for quantification of the dynamic interactions between surface—immobilized proteins and charged particle-emitting imaging probes. In this case, a position sensitive radiation detector layer can be incorporated in a multi-layer microfluidic circuit, as shown in the cross section of the microfluidic circuit (FIG. 2).

A small amount of probe molecules are introduced into the fluidic circuit layer (FIG. 1) where protein is immobilized on the surface of each individual chamber. The control circuit responsible for microchip-operation lies below (Unger, M. A., et al. (2000). Monolithic Microfabricated Valves and Pumps by Multilayer Soft Lithography, Science, 288, 113-6). The radiation sensitive scintillator layer is precisely above the fluidic layer, separated by a minimal distance (10 microns). The material of the control and fluidic layers is PDMS poly(dimethylsiloxane). The scintillation layer, serves the purpose of converting the charged particles of the radiation to light, that can in turn propagate large distances towards a light sensitive camera either via a lens, (FIG. 2a), or via a fiber-optic plate (FIG. 2b), for example. In the case of FIG. 2a, the detector can be spaced at a distance and coupled via a lens, allowing for flexibility in the device design. In the case of FIG. 2b, the detector can be directly coupled to the fiber-optic plate, allowing for higher sensitivity.

(ii) When surface-immobilized proteins are replaced by cells, the above mentioned device can be utilized as a microchip-based cellular array for quantification of the dynamic interactions between surface-immobilized cell and imaging probes.

(iii) In a microfluidic chemical reaction circuit designated for the production of radiolabeled imaging probes, an embedded radiation detector can form a conjunction with microchip-based high performance liquid chromatography (HPLC) to determine production purity and yield.

Tseng's research group has been involved with the development of a variety of microfluidic technological platforms including (i) microfluidic devices with chemical reaction circuits (CRCs) (a CTI/UCLA joint patent application, CTI#4255-PCT, was filed on December 3^{rd} to cover this invention (PCT Int. Appl. (2006), WO 2006042276). and (ii) an integrated mouse blood sampler for mice (a provisional patent application, UCLA case# 2005-659-1 has been filed in September 2005 to cover this invention. These inventions can be used to facilitate the discovery pathway of new molecular imaging probes, since only tiny sample amounts are required in the probe production and evaluation, and microchips can be rapidly designed and produced to meet the needs of different purposes for different probes. For example, biomarkers with scarce abundance (around pico-gram level) in nature can be radio- and/or fluorophore-labeled for further evaluation in molecular imaging and other biological applications. This is not feasible using conventional bench-top labeling approaches for the following reasons. Although these microchip-based platforms can offer many advantages by miniaturizing the device size and reducing the probe consumption, there are significant challenges accompanied with the advantages. First, since the microchips are small, it is difficult for existing tomographic imaging technology to quantify the probe distribution on the chip with a reasonable spatial resolution. Second, since only a small amount of probe is available, the sensitivity of existing tomographic technology is inadequate to detect the low level of probes. These two problems limit further application of this microchip-based technology in the fields of biological assay and chemical analysis. They require higher 2-D spatial resolution and significantly higher sensitivity than conventional techniques. The current invention can solve some or all of these problems according to some embodiments.

Radioactively labeled probes emit a variety of particles, charged and uncharged. The embedded radiation detector described here pertains to the detection of charged particle emissions. Charged particles tend to travel small distances in matter (˜mm) and undergo many interactions during their tortuous path. The most commonly produced charged particle is the electron (β³¹) or the positron (β⁺), but the device principle in this invention also works with heavier energetic alpha particles (α).

For in-vivo imaging detection of positrons, the following is the traditional approach: A positron emitted by a molecular probe at the end of its path is annihilated with a nearby electron, producing two co-linear gamma rays (511 keV). These gammas travel in opposite directions and can be detected at significant distances (˜m) with specialized detectors. This collinear, long distance path allows for Positron Emission Tomography (PET) as a non-invasive in-vivo imaging method. The efficiency of this process though is limited by the detection sensitivity of the PET tomographic system for the 511 kev gammas. For technical and cost reasons, the efficiency of PET measurements for coincidence detection of these gammas is on the order of 5% at the “sweet spot” center of a PET scanner, and drops linearly to zero at the edges of the field of view. This means that out of every 100 charged particles (positrons) emitted, only 5 will be detected as valid events, under ideal circumstances. Furthermore, this sensitivity can be achieved with a device that costs on the order of several hundreds of thousands of dollars.

The application described in this invention is not the detection of the presence of the positron emitting molecule in-vivo, but its detection inside a microfluidic chip. If instead of detecting the 511 keV gammas, one directly detects the charged particles, several key advantages can be realized, for example: (a) Significantly increased charged particle collection efficiency, (b) significantly lower detection limit (c) capability to detect and quantify other charged particle emitters in addition to positrons (β′ and α) The very efficient, cost effective and versatile method to detect charged particles used here is the scintillation process.

An operating principle for this invention is as follows: A fluid containing the radiolabeled probe is injected into the microfluidic device and follows a spatial and temporal distribution. Due to the nature of the microfluidic device, a very thin (10 micron) film of material could be used to separate the microfluidic chip from a charged particle sensitive scintillator plate (FIG. 2).

This scintillator plate material will absorb the majority of the emitted charged particles and will convert their energy to visible light photons. A sensitive light camera then can take images of the distribution of light produced by the scintillator plate. These images will in turn reflect the spatial and temporal distribution of the radioactive probe in the chip. The time constant of the scintillation process for most common scintillator materials is on the order of nanoseconds, and therefore the temporal resolution of the device in this example is mainly limited by the frame acquisition rate of the photodetector (light camera) in use. The sensitivity of this approach for the detection of positrons can be several orders of magnitude higher than the sensitivity of a state of the art PET tomograph because: (a) More than 60% of the charged particles will deposit at least some energy in the scintillator, even if the scintillator has a semi-infinite slab geometry. Therefore the 5% peak particle detection efficiency is turned into a >60% average efficiency. (b) There is no need for tomographic data reconstruction reducing the number of necessary angles of view from more than 100, to 1. Results for one example are illustrated below to further explain this rationale. For SPECT emitting probes, the same technology will yield much higher sensitivity gains, as SPECT tomographic imaging systems are inherently 100-1000 times less sensitive than PET scanners, due to the presence of a lead collimator.

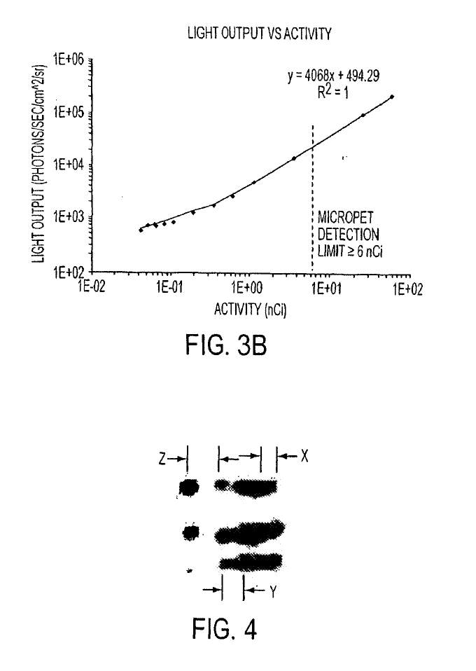

A clear plastic scintillator plate measuring 45×29×2.7 mm³ was plated with a small amount of a common radioactive molecular imaging probe emitting positrons (¹⁸FDG). The exact amount of radioactivity was quantified with a calibrated well counter. The scintillator plate was subsequently placed inside a light tight black box equipped with a cooled CCD camera and imaged repeatedly over a period of 12 hours, during the decay of the ¹⁸F source (109.7 min half-life). Imaging of the scintillator plate was performed in 5 minute frames, thereby making the decay of the source within each time frame insignificant. A total of 13 time frames were acquired in this 12 hour experiment. Regions of interest were drawn over the resulting images (FIG. 3a), and the scintillation photons collected by the CCD camera were plotted as a function of the known source activity (FIG. 3b).

It can be seen from FIG. 3b, that the response of this approach is linear even for this rudimentary prototype demonstration setup, with a correlation coefficient of 1. This result indicates that the system can work linearly over a large range of activities. While in this test we were interested in the lower end of the sensitivity, a system based on this technology can very easily detect much larger levels of activity (many log orders). As a reference point, the absolute limit of activity detection with a tomographic state of the art small animal PET scanner under ideal circumstances is illustrated in FIG. 3b (˜6-10 nCi).

Because scintillation light photons tend to scatter and travel longer distances than charged particles, producing a diffuse light background, we performed a similar experiment with multiple adjacent wells separated by a variable distance. The results of this experiment, illustrated in FIG. 4, indicate that we can easily increase the density of the microfluidic chip layout wells to about 1.5 mm. Much higher spatial resolution can be achieved by light collimation within the scintillator.

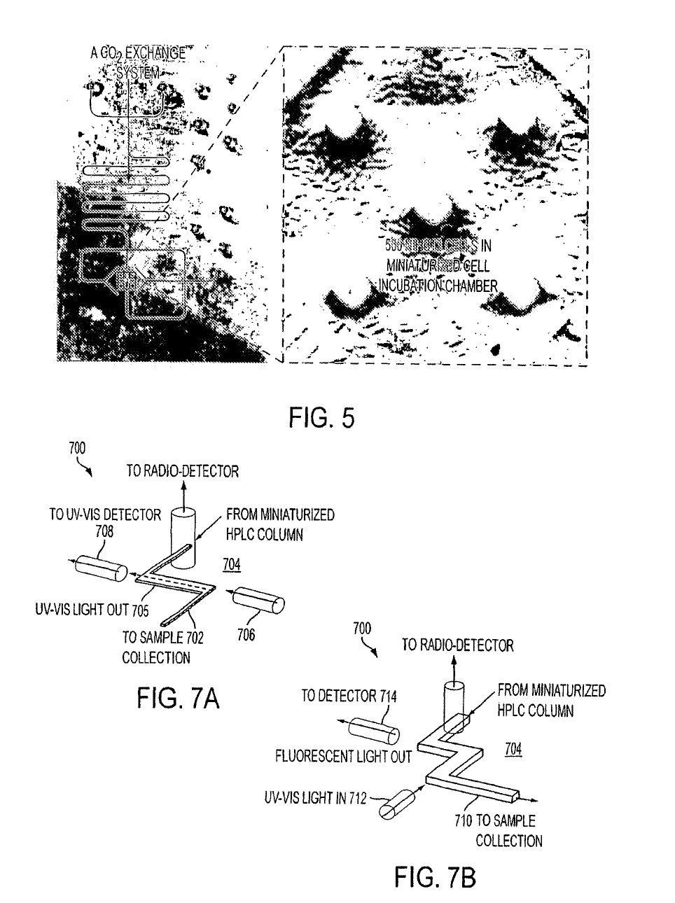

In collaboration between the Witte's and Tseng's groups in UCLA Pharmacology, a microchip-based cell incubator (FIG. 5) with dimensions 1 mm×1 mm×0.04 mm has been developed to perform cell culturing in a miniaturized fashion. Both NIH3T3 and HeLa cell lines can be maintained in these microfluidic culture chambers for about a week. In this example according to the current invention, there are four microchannels connected to the cell incubation chamber: one pair will be employed for introducing cells and the other pair will be used as perfusion channels for continuous delivery of culture media and nutrient. To avoid dead volume during culture medium perfusion. a number of small channels (2 μm wide) are integrated along the edge of the cell chamber to generate uniform flow. In addition, a gas exchange system was coupled with one of the medium/nutrient channels to ensure constant supply of CO₂ for maintaining the pH value of the cell culture environment. One may, for example, integrate a number (e.g., 10) of cell incubation chambers on a single microchip to form a miniaturized cell assay, and utilize this cell assay to study cell uptake kinetics of new molecular imaging probes.

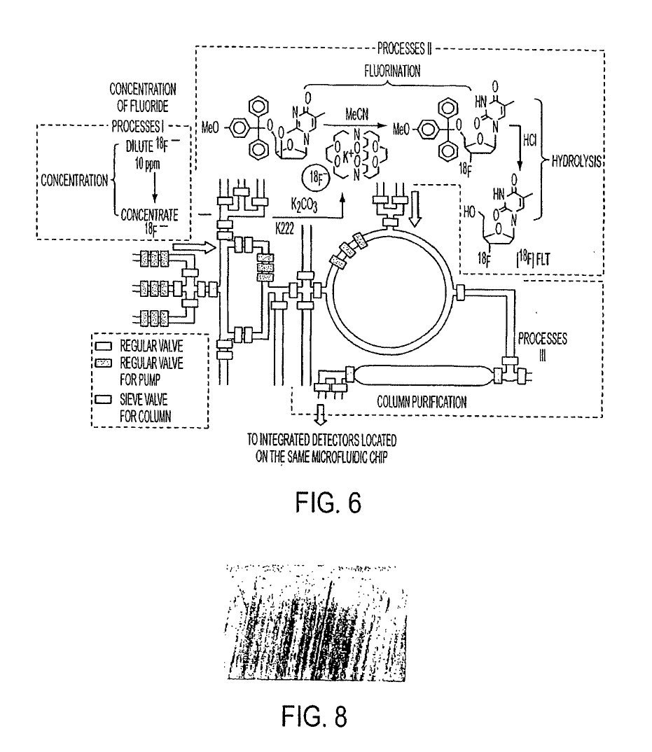

Among a number of [¹⁸F]-radiolabeled imaging probes, the FDG synthesis of is an exceptional example—the yield of FDG production is fairly high (about 80 and 98% using “synthetic box” and microchip, respectively) and the major side product obtained from the radiolabeling reaction is glucose, which exists in biological systems ubiquitously and has almost no influence for the FDG-PET imaging. Using the microchip-based technology for FDG production, the resulting FDG is ready for patient administration after simple treatments, i.e., filtration through a small Al₂O₃ cartridge and sterilization by heating. In contrast, the syntheses of FLT and FDDNP are somehow problematic—their reaction yields are relatively low and the reaction side products are complicated, and most importantly, some of these reaction side products are toxic and might compete with the probe molecules in PET imaging. Although FLT and FDDNP can be obtained by the microchip-based technology, the resulting products still have to be further purified by high performance liquid chromatography (HPLC) under a macroscopic setting prior to the utilization in patient imaging. Therefore, to incorporate a chip-based purification module, namely, a miniaturized HPLC purification system in the same microfluidic chip will improve the production efficiency of FLT and FDDNP. Currently, Tseng's research group is working on the design and fabrication of a new generation of microfluidic chip (FIG. 6), in which an additional miniaturized HPLC system for on-chip analysis and purification of FLT, FDDNP as well as the other existing and new molecular imaging probes, is incorporated at the terminus of the entire microfluidic circuit. In fact, a microfluidic column has been described in the patent application of “Chemical Reaction Circuits” for fluoride concentration purpose. Following the same design, a variety of miniaturized HPLC columns, filled with different types of stationary phases and having different lengths can be designated to meet the requirements of different radiolabeled imaging probes.

A bench-top HPLC system employed for analysis and purification of the radiolabeled PET imaging probes is generally composed of HPLC pumps, columns, a radio-detector and a UV-Vis detector. These two parallel-operated detectors allow one to better characterize the resulting products.

Some portions of a microfluidic device 700 are illustrated schematically in FIGS. 7a and 7b. In FIG. 7a, a UV-Vis detection structure is illustrated in addition to a charged particle detection structure. The microfluidic device 700 may be similar to the microfluidic devices 100, 200 and/or 300 except at least one microfluidic channel 702 in a microfluidic layer 704 has a path similar to the letter “Z” in that it takes two sharp bends and provides a substantially straight portion 705 therebetween. A first optical waveguide 706 can provide a path to illuminate a sample when it is present in the straight portion 705 of the microfluidic channel 702. The optical waveguide can be an optical fiber, for example, or may be constructed integral with the microfluidic layer 704 by forming an appropriate refractive index profile so the optical waveguide channels the desired wavelengths of light there along. An optical waveguide 708 directs light to a detector (not shown in FIG. 7a). The optical waveguide 708 may be similar or substantially the same in construction as the optical waveguide 706. The term “light” used anywhere in this specification is intended to have a broad meaning to encompass electromagnetic waves or photons regardless of whether they are visible to the human eye. Ultraviolet and infrared light is intended to fall within the broad definition of “light” as used herein.

The microfluidic device 700 may have fluorescent light detection structure in place of, or in addition to, one or more structures as illustrated in FIG. 7a. In this case, a microfluidic channel 710 has a structure similar to a “W” shaped path. An illumination optical waveguide 712 is at a nonzero, less than 180 degree angle with respect to a detection optical waveguide 714. This arrangement allows fluorescent light to be detected without being saturated with illumination light.

According to an embodiment of the current invention, a miniaturized radiation detector can be integrated with a fiber optics-based UV-Vis cell (FIG. 7a). The entire detector system can be integrated with a new generation chemical reaction circuit to analyze the resulting product of fluids separated by the chip-based HPLC system. This UV-Vis microcell comprises a “Z-shape” microfluidic channel (with dimensions of 20 to 500 μm in width, 10 to 100 μm in height and 500 μm to a few mm in length) and a pair of micro-size optical fibers which are well-aligned with a microfluidic channel for projecting and receiving light through the central axis of the “Z-shape” microfluidic channel. Following the same concept but with the design of “W-shape” fluidic microchannels, a miniaturized fluorescent cell (FIG. 7b) can also be included. In this case, an optical fiber will be able to send excitation light and the emitted light can be collected by a second fiber, oriented at 90° and connected to a spectrometer configured for fluorescence measurement.

In another embodiment according to the current invention, a cesium iodide crystal may be used in a charged particle detection layer. For example, one can replace the plastic scintillator illustrated in FIG. 2 with a cesium iodide crystal (CsI—an inorganic scintillator crystal). This can improve the spatial resolution for all types of charged particles and also increase the sensitivity to lower energy charged particle emitters, such as ³H. That is because the typical range of charged particles in CsI is less than half the range in plastic. Furthermore, CsI, exists in many forms, one being a microcolumnar structure (FIG. 8). This microcolumnar structure, collimates the scintillation light towards the detector and therefore reduces drastically the light crosstalk. Finally, CsI scintillation light yield is 5 times greater than for most plastic scintillators, allowing for improved sensitivity with lower energy charged particles. However, the broad concepts of the invention are not limited to the specific type of scintillation material used.

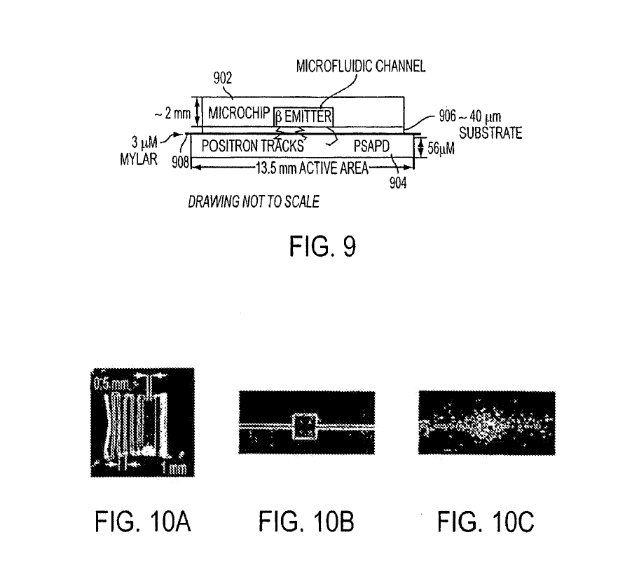

FIG. 9 is a schematic illustration of a microfluidic device 900 according to another embodiment of the current invention. The microfluidic device 900 has a microfluidic circuit layer 902 and a charged particle detection layer 904. The microfluidic circuit layer 902 may be similar to or substantially the same as microfluidic circuit layers 202, 302 and 704 in some embodiments. The charged particle detection layer 904 is a position sensitive avalanche photodiode (PSAPD) according to this embodiment of the current invention. The microfluidic device 900 can also include a microfluidic end layer 906 which can be similar to microfluidic end layers 214, 308, for example. The microfluidic end layer 906 may be a substrate. A Mylar layer 908 may also be provided between the microfluidic circuit layer 902 and the charged particle detection layer 904.

### EXAMPLE 2

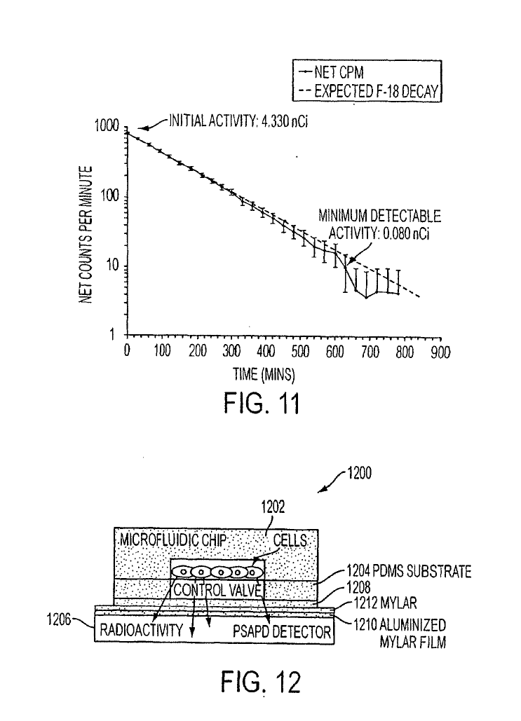

The sensitivity of the device can be improved by substituting for the scintillator layer a position sensitive solid state detector as shown in FIG. 9. One example of a suitable solid state detector is a position sensitive avalanche photodiode (PSAPD). A particular device is manufactured by Radiation Monitoring Devices (www.rmdinc.com) in Watertown, Mass., but other detectors as for example a standard Charge Coupled Device (CCD) can be used (R. Ott, J. MacDonald, and K. Wells, “The performance of a CCD digital autoradiography imaging system,” Physics in Medicine and Biology, vol. 45, pp. 2011-2027, 2000). This particular device though is radiation hardened and will sustain operation in the presence of charged particles without loss in efficiency. Its design is based on a deep diffused high gain avalanche detector that is sensitive to both visible light in the 400-800 nm region (K. S. Shah, R. Farrell, R. Grazioso, E. S. Harmon, and E. Karplus, “Position-sensitive avalanche photodiodes for gamma-ray imaging,” IEEE Transactions on Nuclear Science, vol. 49, pp. 1687-1692, 2002) and charged particles (K. S. Shah, P. Gothoskar, R. Farrell, and J. Gordon, “High efficiency detection of tritium using silicon avalanche photodiodes,” IEEE Transactions on Nuclear Science, vol. 44, pp. 774-776, 1997). The back surface of this PSAPD consists of a resistive layer with four contacts that provide position resolution based on comparison of signal amplitudes. In this manner, the PSAPD produces four position related signals that vary continuously for events occurring across the active surface. FIG. 10(A) shows an example with an image of the distribution of a fluorinated compound (Fluoro Deoxy Glucose—FDG) in a microfluidic circuit. The left side shows a pattern made with linear microfluidic channels 0.1 mm thick and with varying separation between them. The limit of spatial resolution is clearly better than 0.5 mm. FIG. 10(B) shows a visible light photograph of a microwell from a microfluidic chip that contains 4.3 nCi of FDG. That microwell measures 0.25 mm on each side and is 0.065 mm deep. FIG. 10(C) shows the image of the F-18 contained in the solution of the well in FIG. 10(B). A plot of the counts per minute for that microwell as the F-18 activity decays with a 109.7 min half life is shown in FIG. 11. The detection limit for this particular prototype is 0.08 nCi.

FIG. 12 illustrates a microfluidic device 1200 according to another embodiment of the current invention The microfluidic device 1200 has a microfluidic circuit layer 1202, a control circuit layer 1204 and a charged particle detector layer 1206. In this example, the control circuit layer 1204 is arranged between the microfluidic circuit layer 1202 and the charged particle detector layer 1206. The general concepts of this invention are not limited to only this arrangement. For example, other embodiments can include an arrangement in which the control circuit layer 1204 is arranged on top of the microfluidic circuit layer 1202 in the view of FIG. 12 so as to further reduce material between the charged particle emitters and the charged particle detector layer 1206. In this embodiment, an end cap 1208 is provided on the control circuit layer 1204. Further layers can be provided as desired. For example, an aluminized Mylar film 1210 can be provided to shield the PSAPD from ambient light and Mylar layer 1212 can be provided to facilitate removal of the PSAPD from the microfluidic circuit layer 1202 and control circuit layer 1208 after use. This can facilitate the reuse of the PSAPD while permitting one to dispose of other structures of the microfluidic device 1200 after use.

### EXAMPLE 3

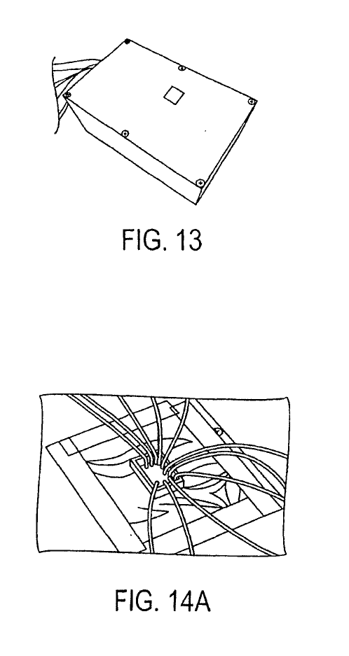

In this example, the detector was sealed on the top surface with two layers of a metalized Mylar film to allow researchers to operate the PSAPD under normal room light. Each layer consisted of a Mylar film (3 μm thick) coated with a thin layer of Aluminum (0.2 μm thick). An additional Mylar film is used as a protective sacrificial layer and disposed of in between uses. FIG. 12 shows a cross sectional schematic of a microfluidic device 1200 according to an embodiment of the current invention, a portion of which may be referred to as a microfluidic chip. The microfluidic chip can be used to incubate live cells with a substrate layer to control the flow of solutions in the channels above. The microfluidic chip sits on top of a 3 μm thick sacrificial Mylar layer to protect the PSAPD top surface. The PSAPD along with the readout electronics was enclosed inside a metal box with the top surface detector exposed, as shown in FIG. 13.

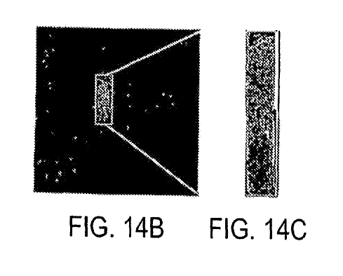

An application of this new device will be to allow imaging and quantification of low amounts of radioactivity in biological samples on a microfluidic platform. FIG. 14(a) shows a photograph of a microfluidic chip used for cell incubation coupled to the PSAPD detector. Experiments were performed with live cells on a microfluidic chip. In these experiments 3T3 mouse fibroblast cells were grown in a microfluidic cell chamber measuring 3 mm×0.5 mm×0.1 mm. Prior to imaging, the glucose medium in the cells chambers was removed and the cells were left in a starved state for one hour. FDG solution was then loaded into the chambers and the cells were allowed to incubate in the FDG solution for an additional hour. The excess FDG solution was then flushed from the chamber leaving only the FDG trapped within the cells. The entire chip was then placed on top of the PSAPD detector and imaged for 5 minutes. FIG. 14(a) shows the setup for this experiment and the image in FIG. 14(b) was obtained with the PSAPD detector. Within the chamber there were approximately 760 total live cells. The image (FIG. 14(b)) shows that the FDG activity was localized within the cell chamber containing the mouse fibroblast cells. A photograph was taken with a microscope to show that the cells were alive and viable after imaging with the PSAPD as shown in the last image (FIG. 14(c)).

Various embodiments of this invention are described herein, including the best mode known to the inventors for carrying out the invention. Of course, variations on those embodiments will become apparent to those of ordinary skill in the art upon reading the foregoing description. The inventor expects skilled artisans to employ such variations as appropriate, and the inventors intend for the invention to be practiced otherwise than specifically described herein. Accordingly, this invention includes all modifications and equivalents of the subject matter recited in the claims appended hereto as permitted by applicable law. Moreover, any combination of the above-described elements in all possible variations thereof is encompassed by the invention unless otherwise indicated herein or otherwise clearly contradicted by context.

Furthermore, numerous references have been made to patents and printed publications throughout this specification. Each of the above cited references and printed publications are herein individually incorporated by reference in their entirety.

In closing, it is to be understood that the embodiments of the invention disclosed herein are illustrative of the principles of the present invention. Other modifications that may be employed are within the scope of the invention. Thus, by way of example, but not of limitation, alternative configurations of the present invention may be utilized in accordance with the teachings herein. Accordingly, the present invention is not limited to that precisely as shown and described.

We claim:

1. A micro-fluidic device, comprising:
a micro-fluidic circuit layer; and
a charged-particle detection layer disposed proximate said micro-fluidic circuit layer,
wherein said micro-fluidic device is constructed to provide a two-dimensional image of charged-particle emissions from a sample within said micro-fluidic circuit layer while in operation.

2. A micro-fluidic device according to claim 1, wherein said charged-particle detector layer comprises a scintillation material.

3. A micro-fluidic device according to claim 2, wherein said scintillation material is a cesium iodide crystal.

4. A micro-fluidic device according to claim 2, wherein said scintillation material is a crystal having a microcolumnar structure arranged to channel light in a desired direction.

5. A micro-fluidic device according to claim 2, further comprising a detection system arranged in optical communication with said scintillation material, said detection system being constructed to detect light produced in said scintillation material by charged particles being detected.

6. A micro-fluidic device according to claim 5, wherein said detection system comprises an imaging sensor and a lens system arranged between said scintillation material and said imaging sensor to image light emitted from said scintillator onto said imaging sensor.

7. A micro-fluidic device according to claim 5, wherein said detection system comprises a fiber-optic plate disposed on said charged-particle detection layer and an imaging sensor disposed on said fiber-optic plate.

8. A micro-fluidic device according to claim 1, wherein said charged-particle detection layer comprises a semiconductor detector.

9. A micro-fluidic device according to claim 1, wherein said charged-particle detection layer comprises a position sensitive avalanche photodiode.

10. A micro-fluidic device according to claim 9, further comprising a sacrificial layer arranged between said charged-particle detection layer and said microfluidic circuit layer, said sacrificial layer being constructed to facilitate removal of said charged-particle detection layer from said microfluidic circuit layer.

11. A micro-fluidic device according to claim 9, further comprising a light shield layer disposed over said charged-particle detection layer, said light shield layer being constructed to shield ambient light from said position sensitive avalanche photodiode.

12. A micro-fluidic device according to claim 1, further comprising a control circuit layer disposed on a surface of said micro-fluidic circuit layer.

13. A micro-fluidic device according to claim 12, wherein said control circuit layer is disposed on a surface of said micro-fluidic circuit layer between said micro-fluidic circuit layer and said charged-particle detection layer.

14. A micro-fluidic device according to claim 1, wherein said micro-fluidic circuit layer defines a micro-fluidic path and comprises an optical waveguide aligned with a portion of said micro-fluidic path.

15. A microfluidic device according to claim 14, wherein said optical waveguide is an optical fiber.

16. A micro-fluidic device according to claim 14, wherein said optical waveguide is suitable to direct at least one of illumination light, transmitted light or fluorescent light.

17. A method of quantification of radioactivity in a biological sample overtime, comprising:
directing a fluid containing said biological material into a microfluidic device;
detecting charged particles emitted from said biological material with a two-dimensional imaging sensor; and
forming a two-dimensional image corresponding to radioactivity of said biological sample over time.

18. A method of quantification of radioactivity over time in a biological sample according to claim 17, wherein said detecting includes detecting charged particles with a position sensitive avalanche photodiode.
